(19) United States
(12) Patent Application Publication
(10) Pub. No.: US 2013/0015317 A1
(43) Pub. Date: Jan. 17, 2013

(54) Vibration Isolation Storage Module

(71) Applicants: Ho-Ching Huang, Taipei City (TW); Hui-Chen Wang, Taipei City (TW); Yi-Chun Tang, Taipei City (TW)

(72) Inventors: Ho-Ching Huang, Taipei City (TW); Hui-Chen Wang, Taipei City (TW); Yi-Chun Tang, Taipei City (TW)

(73) Assignee: PEGATRON CORPORATION, Taipei City (TW)

(21) Appl. No.: 13/548,461

(22) Filed: Jul. 13, 2012

(30) Foreign Application Priority Data
Jul. 15, 2011 (TW) 100125223

(51) Int. Cl. H05K 7/00; F16F 7/00

(52) U.S. Cl. 248/636

(57) ABSTRACT

A vibration isolation storage module used in a computer is disclosed. The vibration isolation storage module includes a storage device, two brackets, a damping-fixing device, and a damping-positioning device. The storage device is disposed on a base of the computer. The two brackets are respectively disposed on two corresponding sides of the storage device. The damping-fixing device has elasticity and is disposed on the brackets to connect the storage device with the bracket and absorbs shock on the storage device with respect to the bracket. The damping-positioning device has elasticity and is disposed on the brackets to connect the bracket with the base and absorbs shock on the bracket with respect to the base.

### BACKGROUND

1. Technology Field

This disclosure generally relates to a vibration isolation storage module for fixing a storage device on a base. More particularly, the disclosure relates to a vibration isolation storage module for fixing a hard drive on a base of means of transport.

2.Description of the Known Art

With the progress of information technology, the use of computers is very popular. Besides being used in the indoor space, computers are also used in means of transport such as cars and boats. One the other hand, the software and information accessed by the computer are mostly stored in a hard drive. Therefore, the hard drive can be seen as the most important data storage device for computers. However, frequent and irregular vibrations usually occur when means of transport run or move. A disk error or computer crash caused by vibrations is easily happened if no proper fixing device is applied to the hard drive.

As the known arts shown in FIGS. 1A and 1B, a common hard drive fixing device includes a box 10 and rubbers or sponges 31, 32, 33, and 34. More particularly, the hared drive 20 is disposed in the box 10, wherein the rubbers or sponges 31, 32, 33, and 34 are respectively disposed between the upper side, the lower side, the left/right side, and the rear side of the hard drive 20 and the inner side of the box 10 for absorbing the shock on the hard drive 20. However, too many kinds and sizes of rubbers or sponges used in known arts are not convenient for assembling. Damage or bending is easily occurred to reduce the anti-vibration effect in the assembling process. Moreover, the rubbers and sponges are disadvantageous to the heat dissipation.

### SUMMARY

It is an object of the disclosure to provide a vibration isolation storage module for use with a computer, wherein the vibration isolation storage module increases the shake endurance of the storage device and decreases the disk error or computer crash caused by vibrations.

One embodiment of the vibration isolation storage module includes a storage device, two brackets, a damping-fixing device, and a damping-positioning device. The storage device is disposed on a base of the computer. The brackets are respectively disposed on two corresponding sides of the storage device. The damping-fixing device has elasticity and is disposed on the bracket to connect the storage device with the bracket and absorb shock on the storage device with respect to the bracket. The damping-positioning device has elasticity and is disposed on the bracket to connect the bracket with the base and absorb shock on the bracket with respect to the base. The direction of the shock absorbed by the damping-fixing device is different from the direction of the shock absorbed by the damping-positioning device.

In the embodiment, the vibration isolation storage module further includes a signal mount disposed on another side adjacent to the two sides of the storage device and passed through by a signal transmitting line connecting to the storage device. The vibration isolation storage module further includes a stopper and an anti-loose member. The stopper is disposed on the base and faces the signal mount. The anti-loose member has elasticity. The stopper props up the anti-loose member, wherein the anti-loose member is disposed between the signal mount and the stopper. The vibration isolation storage module further includes a counterweight block disposed on the bottom side of the storage device and between the two brackets.

In the embodiment, each of the two brackets includes a fixing part and a positioning part. The fixing part is disposed at the position that the bracket connects to the storage device. The positioning part is disposed at an end of the bracket. The damping-fixing device includes a fixing pivot part and a fixing wheel part. The fixing pivot part connects to the storage device. The fixing wheel part takes the fixing pivot part as a pivot and has elasticity, wherein the fixing wheel part is able to deform in a radial direction. The tread of the fixing wheel part engages in the fixing part. The fixing part includes a hole for the fixing wheel part to engage therein. The hole includes an entering hole and a fixing hole connected to the entering hole, wherein the diameter of the entering hole is larger than the diameter of the fixing hole. The entering hole partially overlaps the fixing hole. The tread of the fixing wheel part engages in the fixing hole. The tread of the fixing wheel part is concave in the radial direction.

In the embodiment, the damping-positioning device includes a positioning part and a positioning wheel part. The positioning part connects to the base. The positioning wheel part takes the positioning pivot part as a pivot and has elasticity, wherein the positioning wheel part is able to deform in a radial direction. The tread of the positioning wheel part engages in the positioning part. The tread of the positioning wheel part is concave in the radial direction.

### BRIEF DESCRIPTION OF THE DRAWINGS

FIGS. 1A and 1B are schematic views of prior arts;

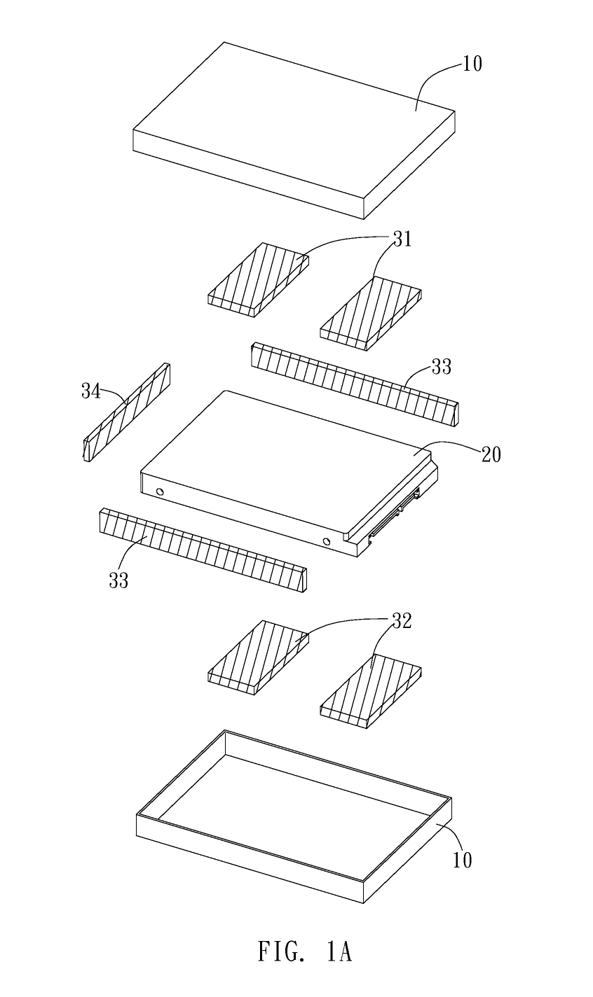

FIG. 2 is a explosive diagram of the preferred embodiment of the present invention;

FIG. 3 is a schematic view of the preferred embodiment of the present invention; and

FIG. 4 is a cross-sectional view of the preferred embodiment of the present invention.

### DETAILED DESCRIPTION OF THE PREFERRED EMBODIMENT

The vibration isolation storage module of present invention is used in a computer. In the preferred embodiment, the computer may be disposed on means of transport. More particularly, the vibration isolation storage module of present invention is used in a computer disposed on a vehicle. In other embodiments, however, the computer may be placed in a static environment and is not limited to be connected to a mean of transport. In addition to vehicles, the means of transport also include boats and aircrafts.

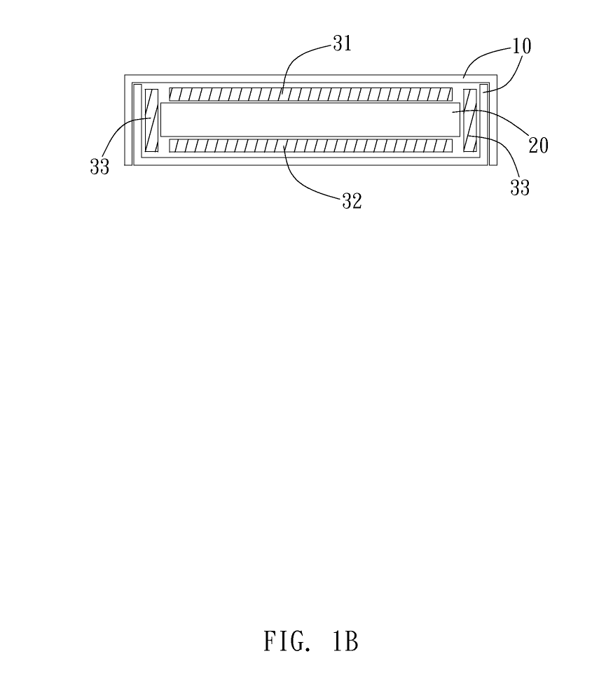

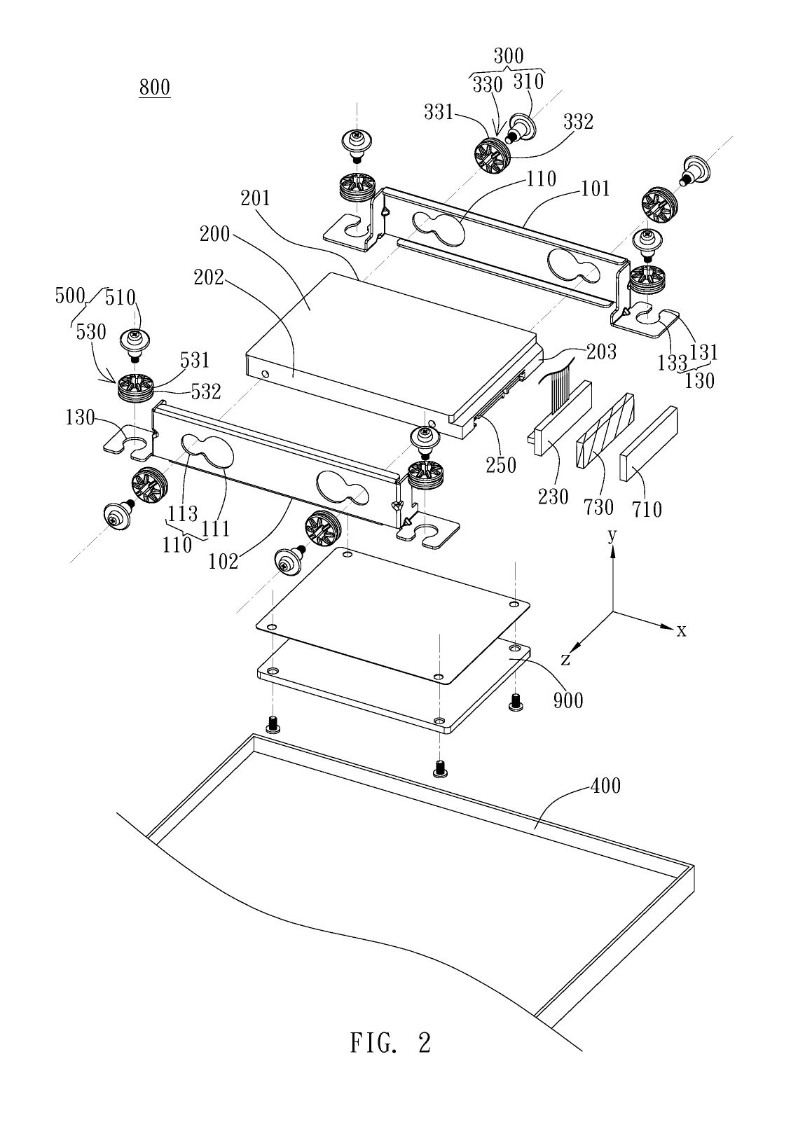

As the preferred embodiment shown in FIGS. 2 and 3, the vibration isolation storage module 800 includes a storage device 200, two brackets 101 and 102, a damping-fixing device 300, and a damping-positioning device 500. The brackets 101 and 102 are respectively disposed on two corresponding sides of the storage device 200, i.e. the side 201 and the side 202. In the preferred embodiment, each of the brackets 101 and 102 includes a fixing part 110 and a positioning part 130. The fixing part 110 of the bracket 101 and the fixing part 110 of the bracket 102 are respectively disposed at the position that the brackets 101 and 102 connect to the storage device 200. The positioning part 130 of the bracket 101 and the positioning part 130 of the bracket 102 are respectively disposed at an end of the bracket 101 and an end of the bracket 102. More particularly, in the preferred embodiment shown in FIG. 2, brackets 101 and 102 are long sheets respectively extending along the x direction and parallel to the side 201 and the side 202 of the storage device 200. The brackets 101 and 102 include protruding fins parallel to the base 400 at respective two ends of the brackets 101 and 102.

As the preferred embodiment shown in FIG. 2, the damping-fixing devices 300 have elasticity and are respectively disposed on the fixing parts 110 of the brackets 101 and 102 to connect the storage device 200 with the brackets 101 and 102 and absorb shock on the storage device 200 with respect to the brackets 101 and 102. The damping-positioning devices 500 have elasticity and are respectively disposed on the positioning parts 130 of the brackets 101 and 102 to connect the brackets 101 and 102 with the base 400 and absorb shock on the brackets 101 and 102 with respect to the base 400.

As the preferred embodiment shown in FIG. 2, the damping-fixing device 300 includes a fixing pivot part 310 and a fixing wheel part 330. The fixing pivot part 310 connects to the storage device 200. The fixing wheel part 330 takes the fixing pivot part 310 as a pivot and has elasticity, wherein the fixing wheel part 330 is able to deform in the radial direction. The tread 331 of the fixing wheel part 330 engages in the fixing part 110. In other words, the fixing wheel part 330 is able to deform along the x-y plane. Accordingly, the fixing wheel parts 330 are able to absorb shock on the storage device 200 with respect to the brackets 101 and 102 along the x-y plane. The fixing pivot parts 310 are preferably but not limited to screws, wherein the fixing wheel parts 330 can be screwed onto the storage device 200 by the fixing pivot parts 310. The fixing part 110 includes a hole for the fixing wheel part 330 to engage therein. In the preferred embodiment, the fixing part 110 is a hole constructed by an entering hole 111 and a fixing hole 113, wherein the diameter of the entering hole 111 is larger than the diameter of the fixing hole 113. The entering hole 111 partially overlaps the fixing hole 113, i.e. the entering hole 11 communicates with the fixing hole 113. The fixing wheel part 330 can be inserted into the entering hole 111 and moves to the fixing hole 113 for making the tread 331 of the fixing wheel part 330 engage in the fixing hole 113.

In order to achieve a better engagement between the tread 331 of the fixing wheel part 330 and the fixing hole 113, the diameter of the fixing wheel part 330 is approximately larger than or equal to the diameter of the fixing hole 113. The diameter of the entering hole 111 is larger than the diameter of the fixing hole 113, so that the fixing wheel part 330 can be easily inserted into the entering hole 111 and move to the fixing hole 113 to be screwed onto the storage device 200 by the fixing pivot parts 310. Accordingly, the assembling of the fixing wheel part 330 is more convenient. In order to achieve a better engagement between the fixing wheel part 330 and the fixing hole 113, the tread 331 of the fixing wheel part 330 is concave in the radial direction to form a tread concave part 332, wherein the rim of the fixing hole 113 engages in the tread concave part 332 when the fixing wheel part 330 engages in the fixing hole 113.

As the preferred embodiment shown in FIG. 2, the damping-positioning device 500 includes a positioning part 510 and a positioning wheel part 530. The positioning part 510 connects to the base 400. The positioning wheel part 530 takes the positioning pivot part 510 as a pivot and has elasticity, wherein the positioning wheel part 530 is able to deform in the radial direction. The tread 531 of the positioning wheel part 530 engages in the positioning part 130. The tread 531 of the positioning wheel part 530 is concave in the radial direction. In other words, the positioning wheel part 530 is able to deform along the x-z plane. Accordingly, the positioning wheel parts 530 are able to absorb shock on the brackets 101 and 102 with respect to the base 400 along the x-z plane. The positioning pivot parts 510 are preferably but not limited to screws, wherein the positioning wheel parts 530 may be screwed onto the base 400 by the positioning pivot parts 510. In the preferred embodiment, the positioning parts 130 are perforations 133 disposed at the ends of the brackets 101 and 102 and have openings 131 on the edges, wherein the width of the opening 131 is smaller than the diameter of the perforation 133. The positioning wheel part 530 can be inserted from the opening 131 and move to the perforation 133, so that the tread 531 of the positioning wheel part 530 engages in the perforation 133.

In order to achieve a better engagement between the tread 531 of the positioning wheel part 530 and the perforation 133, the diameter of the positioning wheel part 530 is approximately larger than or equal to the diameter of the perforation 133. The opening 131 is provided so that the positioning wheel part 530 can be easily inserted and move to the perforation 133 to be screwed onto the base 400 by the positioning pivot parts 510. Accordingly, the assembling of the positioning wheel part 530 is more convenient. In order to have a better engagement between the positioning wheel part 530 and the perforation 133, the tread 531 of the positioning wheel part 530 is concave in the radial direction to form a tread concave part 532, wherein the rim of the perforation 133 engages in the tread concave part 532 when the positioning wheel part 530 engages in the perforation 133.

To sum up, the fixing wheel parts 330 are able to absorb shock on the storage device 200 with respect to the brackets 101 and 102 along the x-y plane. The positioning wheel parts 530 are able to absorb shock on the brackets 101 and 102 with respect to the base 400 along the x-z plane. Therefore, the shock on the storage device 200 with respect to the base 400 along the x-y plane and the x-z plane are both absorbed. In other words, the direction of the shock absorbed by the damping-fixing device 300 is different from the direction of the shock absorbed by the damping-positioning device 500. In the preferred embodiment, the base 400 is connected to means of transport. Using the vibration isolation storage module of the present invention, the influence of the shock in different directions on the storage device during the movement of the means of transport is decreased. Therefore, the shake endurance of the storage device is increased and the disk error or computer crash caused by vibrations is decreased.

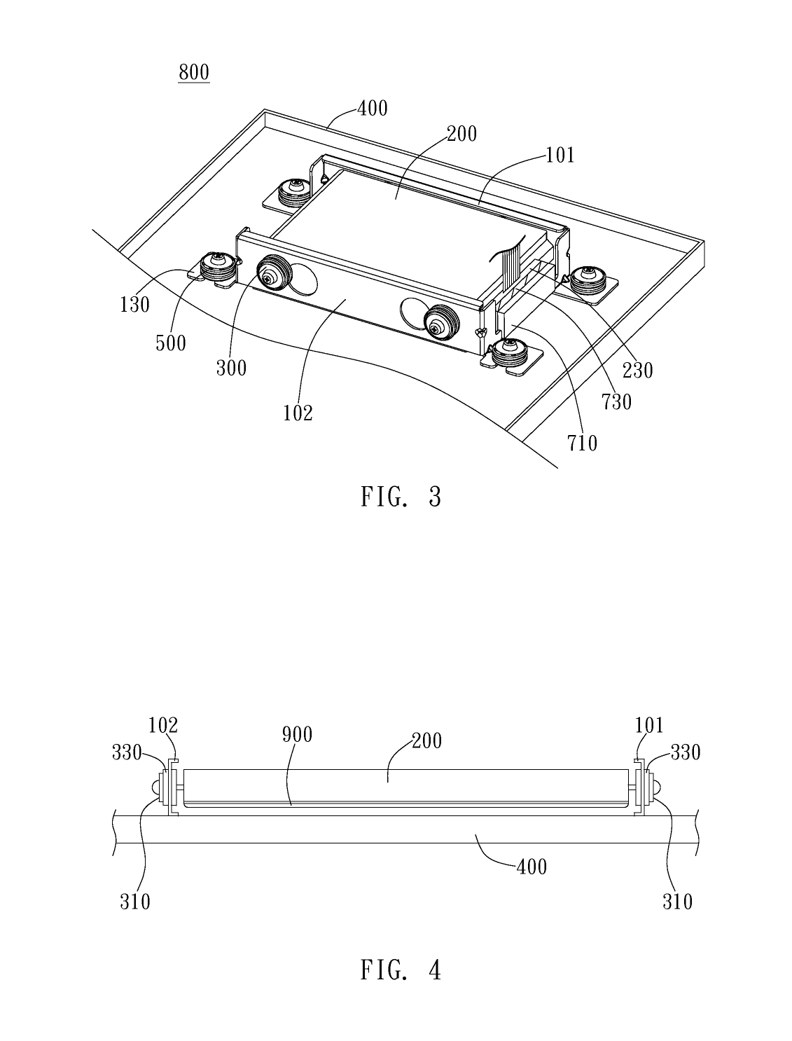

On the other hand, as the embodiment shown in FIG. 4, there is a gap between the storage device 200 and the base 400. Besides being as a buffer space for the storage device 200 to move when the base 400 vibrates, the gap is also benefit to the heat dissipation of the storage device 200. Compared to prior arts that rubbers or sponges are disposed around the storage device, the vibration isolation storage module 800 (see FIG. 2) is connected to the storage device 200 merely by the damping-fixing device 300. Therefore, the storage device 200 in the present invention has a better heat dissipation effect. Moreover, too many kinds and sizes of rubbers and/or sponges are used in prior arts, hence damage or bending is easily occurred. Comparatively, the vibration isolation storage module 800 is connected to the storage device 200 by the damping-fixing device 300, the convenience and the stability of the assembling can be enhanced.

As the preferred embodiment shown in FIG. 2, the vibration isolation storage module further includes a signal mount 230 disposed on another side 203 adjacent to the two sides 201 and 202 of the storage device 200 and is passed through by a signal transmitting line connecting to the storage device 200. More particularly, as shown in FIG. 3, the signal mount 230 can be mounted into a signal slot 250 disposed on the side 203 for coupling the storage device 200 with an external circuit (not shown). The vibration isolation storage module 800 further includes a stopper 710 and an anti-loose member 730. The stopper 710 is disposed on the base 400 and faces the signal mount 230. The anti-loose member 730 has elasticity. The stopper 710 props up the anti-loose member 730, wherein the anti-loose member 730 is disposed between the signal mount 230 and the stopper 710. The stopper 710 is fixed on the base 400 and the anti-loose member 730 is disposed between the signal mount 230 and the stopper 710, so that the anti-loose member 730 generates an elastic force caused by the compression to push the signal mount 230 against the storage device 200. As a result, it can prevent the signal mount 230 from loosening from the storage device 200.

As the preferred embodiment shown in FIG. 2, the vibration isolation storage module 800 further includes counterweight blocks 900 disposed on the bottom side of the storage device 200 and between the two brackets 101 and 102. Substantially, the storage device 200 and the counterweight blocks 900 can be seen as a whole. In other words, the weight of the storage device 200 can be increased by attaching the counterweight blocks 900. Since the inertia is proportional to the weight, the stability of the storage device 200 can be enhanced.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A vibration isolation storage module used in a computer, comprising:
a storage device disposed on a base of the computer;
two brackets respectively disposed on two corresponding sides of the storage device;
a damping-fixing device having elasticity and disposed on the bracket to connect the storage device with the bracket, wherein the damping-fixing device absorbs shock on the storage device with respect to the bracket; and
a damping-positioning device having elasticity and disposed on the bracket to connect the bracket with the base, wherein the damping-positioning device absorbs shock on the bracket with respect to the base.

2. The vibration isolation storage module of claim 1, further comprising a signal mount disposed on another side adjacent to the two sides of the storage device and passed through by a signal transmitting line connecting to the storage device.

3. The vibration isolation storage module of claim 2, further comprising:
a stopper disposed on the base and faces the signal mount; and
an anti-loose member having elasticity, wherein the stopper props up the anti-loose member; wherein the anti-loose member is disposed between the signal mounting and the stopper.

4. The vibration isolation storage module of claim 1, further comprising a counterweight block disposed on the bottom side of the storage device and between the two brackets.

5. The vibration isolation storage module of claim 1, wherein the direction of the shock absorbed by the damping-fixing device is different from the direction of the shock absorbed by the damping-positioning device.

6. The vibration isolation storage module of claim 1, wherein each of the two brackets includes:
a fixing part disposed at the position that the bracket adjacently connects to the storage device; and
a positioning part disposed at an end of the bracket.

7. The vibration isolation storage module of claim 6, wherein the damping-fixing device includes:
a fixing pivot part connecting to the storage device; and
a fixing wheel part taking the fixing pivot part as a pivot and having elasticity, wherein the fixing wheel part is able to deform in a radial direction, wherein the tread of the fixing wheel part engages in the fixing part.

8. The vibration isolation storage module of claim 7, wherein the fixing part includes a hole for the fixing wheel part to engage therein.

9. The vibration isolation storage module of claim 8, wherein the hole includes an entering hole and a fixing hole connected to the entering hole, wherein the diameter of the entering hole is larger than the diameter of the fixing hole, the entering hole partially overlaps the fixing hole, the tread of the fixing wheel part engages in the fixing hole.

10. The vibration isolation storage module of claim 9, wherein the tread of the fixing wheel part is concave in the radial direction.

11. The vibration isolation storage module of claim 9, wherein the damping-positioning device includes:
a positioning part connecting to the base: and
a positioning wheel part taking the positioning pivot part as a pivot and having elasticity, wherein the positioning wheel part is able to deform in a radial direction, wherein the tread of the positioning wheel part engages in the positioning part.

12. The vibration isolation storage module of claim 11, wherein the tread of the positioning wheel part is concave in the radial direction.

13. The vibration isolation storage module of claim 1, wherein a gap exists between the storage device and the base.
